(19) United States
(12) Patent Application Publication
(10) Pub. No.: US 2026/0276736 A1
(43) Pub. Date: Sep. 17, 2026

(54) METHOD OF AUTOMATICALLY SEARCHING FOR LEAKAGE CURRENT PATH

(71) Applicant: Renesas Design (UK) Limited, Bourne End (GB)

(72) Inventors: Viktor KHOMENKO, Newcastle upon Tyne (GB); Russell Christopher GILES, Southrop (GB); Danil SOKOLOV, Newcastle Upon Tyne (GB); Peter Robert BELL, Wokingham (GB)

(73) Assignee: Renesas Design (UK) Limited, Bourne End (GB)

(21) Appl. No.: 19/077,757

(22) Filed: Mar. 12, 2025

(51) Int. Cl. G01R 31/52; G01R 31/26

(52) U.S. Cl. CPC G01R 31/52; G01R 31/2621

(57) ABSTRACT

A computer implemented method of automatically searching for one or more leakage current paths in an electronic circuit comprising receiving a circuit design description of the electronic circuit, analyzing the circuit description to identify a first power rail terminal, searching, starting from the first power rail terminal, for one or more current paths to a second power rail terminal via one or more circuit components, reporting, for at least one current path between the first power rail terminal and the second power rail terminal via the one or more circuit components, a leakage current path, and/or reporting that there are no leakage current paths if no current paths between the first power rail terminal and the second power rail terminal are identified.

### FIELD

The present disclosure relates to a computer implemented method of automatically searching for one or more leakage current paths in an electronic circuit.

### BACKGROUND

Current leakage in an electronic circuit may indicate a design mistake and can lead to various unintended consequences such as:
Functional failures, performance and stability issues, heat issues, reduced battery life of a product, and reduced operational life of the product.
Increased engineering cost, for example relating to debugging, determining workarounds for issues, and implementing design changes.
Metal or full silicon re-spins, which is very costly, and can introduce long delays in the delivery of microchip products.

Electronic design automation (EDA) describes software tools for the design of electronic circuits as may be implemented as an integrated circuit (IC). EDA tools can be used to design and analyse the performance of electronic circuits prior to their manufacture as part of an IC.

Modern semiconductor chips can include billions of components and therefore EDA tools, which automate aspects of the process, are essential in electronic circuit design and analysis.

A combination of factors can cause undesired current leakage and significant computation power may be required for the analysis of realistic circuits. Therefore, current leakage detection can only realistically be applied through software-based automation. Therefore, known EDA tools may provide current leakage detection functionality to enable circuit designers to improve their designs.

Currently there are various known ways to detect leakage paths and/or current leakage including:
Static checkers based on Electrical Rule Check (ERC). An ERC ensures that integrated circuits work as they should, but they are subject to shortcomings.
Dynamic checkers based on transient simulation. These suffer from complex setup, project development kit (PDK) dependencies, slow transient simulation speeds, are generally run late in the design/verification cycle, and require a separate run for each combination of input conditions.
Dynamic connectivity-based checkers. These also suffer from a relatively complex setup, and they are generally focused on digital logic.
Floating nodes checker. There are pre-existing ‘floating node check’ implementations that fall under ‘Static checkers’ and ‘Dynamic checkers’ with various strengths and limitations.

The previously mentioned floating nodes checker is a dynamic checker utilizing a graph-based approach. A floating nodes checker detects leakage paths due to single or multiple floating nodes, has a simple setup and is easy to use, thereby complimenting transient-based approaches. However, its performance can be limiting.

For example, it may take hours or even days to complete for larger designs (for example including more than 20,000 nodes, i.e. wires). Sometimes, it may even fail to complete. This limits the ‘run early and run often’ use model to small designs or small blocks.

It also has other limitations such as:
Limited coverage of input conditions in some cases. For example, it may not cover all possible input conditions e.g. due to excessive running time of the tool.
It cannot automatically handle sequential elements.
There is a limit on the number of multiple floating nodes considered when identifying a leakage path (usually 2-3, otherwise the tool is too slow).
The tool is restricted to systems having floating nodes and cannot identify current leakage due to other causes.

### SUMMARY

It is a desirable to provide an improved method for current leakage detection in electronic circuit designs that exhibits improvements over known systems.

Furthermore, it is desirable to provide an improved EDA system with improved current leakage detection functionality.

According to a first aspect of the disclosure there is provided a computer implemented method of automatically searching for one or more leakage current paths in an electronic circuit comprising receiving a circuit design description of the electronic circuit, analyzing the circuit description to identify a first power rail terminal, searching, starting from the first power rail terminal, for one or more current paths to a second power rail terminal via one or more circuit components, reporting, for at least one current path between the first power rail terminal and the second power rail terminal via the one or more circuit components, a leakage current path, and/or reporting that there are no leakage current paths if no current paths between the first power rail terminal and the second power rail terminal are identified.

Optionally, the circuit design description comprises circuit component information and connectivity information.

Optionally, the circuit design description comprises a graph data structure comprising nodes and one or more arcs, each of the one or more arcs connects a pair of distinct nodes, each node connects one or more terminals of one of the one or more circuit components, and each arc represents at least a portion of a path through one of the one or more circuit components.

Optionally, searching for each of the one or more current paths comprises traversing from a first power rail node that represents the first power rail terminal to a second power rail node that represents the second power rail terminal via at least one of the one or more arcs.

Optionally, traversing from the first power rail node to the second power rail node comprises traversing from the first power rail node to the second power rail node via one or more successive nodes.

Optionally, the computer implemented method comprises defining a plurality of input conditions for the electronic circuit, wherein searching for the one or more current paths comprises applying each of the plurality of input conditions to the circuit design description, and searching for the one or more current paths for each of the plurality of input conditions.

Optionally, the plurality of input conditions comprises voltage levels.

Optionally, defining the plurality of input conditions for the electronic circuit comprises identifying a plurality of input settings for the electronic circuit, removing one or more of the plurality of input settings based on a pre-defined condition, and generating the plurality of input conditions, using the plurality of input settings after removal.

Optionally, the one or more circuit components comprises one or more conducting devices, and/or one or more floating gate field effect transistors (FET), each with a floating gate.

Optionally, the computer implemented method comprises identifying the one or more floating gate FETs prior to searching for the one or more current paths.

Optionally, identifying the one or more floating gate FETs comprises propagating voltage levels through nodes of the circuit design description, identifying nodes having no propagated voltage level as being floating nodes, and identifying FETs in the circuit design description having gates with floating nodes as being floating gate FETs.

Optionally, the computer implemented method comprises defining a plurality of input conditions for the electronic circuit, wherein searching for the one or more current paths comprises applying each of the plurality of input conditions to the circuit design description by applying each of the plurality of input conditions to at least one of the one or more circuit nodes, and searching for the one or more current paths for each of the plurality of input conditions.

Optionally, defining the plurality of input conditions for the electronic circuit comprises identifying a plurality of input settings for the electronic circuit by performing a search using a solver.

Optionally, the solver is a boolean satisfiability (SAT) solver.

Optionally, defining the plurality of input conditions for the electronic circuit comprises identifying a plurality of input settings for the electronic circuit, removing one or more of the plurality of input settings based on a pre-defined condition, and generating the plurality of input conditions, using the plurality of input settings after removal.

Optionally, at least one of the one or more conducting devices comprises a FET, and applying each of the plurality of input conditions to at least one of the one or more conducting devices comprises applying each of the plurality of input conditions to at least one of the one or more circuit nodes.

Optionally, searching for the one or more current paths comprises using a solver to search for the one or more current paths.

Optionally, the solver is a Boolean Satisfiability (SAT) solver.

According to a second aspect of the disclosure there is provided an automatic leakage current detection system configured to receive a circuit design description of an electronic circuit, analyze the circuit description to identify a first power rail terminal, search, starting from the first power rail terminal, for one or more current paths to a second power rail terminal via one or more circuit components, report, for at least one current path between the first power rail terminal and the second power rail terminal via the one or more circuit components, a leakage current path, and/or report that there are no leakage current paths if no current paths between the first power rail terminal and the second power rail terminal are identified.

It will be appreciated that the automatic leakage current detection system of the second aspect may include features set out in the first aspect and can incorporate other features described herein.

According to a third aspect of the disclosure there is provided a non-transitory computer-readable storage medium having stored thereon instructions that when executed by a computer cause the computer to carry out a method of automatically searching for one or more leakage current paths in an electronic circuit comprising receiving a circuit design description of the electronic circuit, analyzing the circuit description to identify a first power rail terminal, searching, starting from the first power rail terminal, for one or more current paths to a second power rail terminal via one or more circuit components, reporting, for at least one current path between the first power rail terminal and the second power rail terminal via the one or more circuit components, a leakage current path, and/or reporting that there are no leakage current paths if no current paths between the first power rail terminal and the second power rail terminal are identified.

It will be appreciated that the non-transitory computer-readable storage medium of the third aspect may include features set out in the first aspect and/or the second aspect and can incorporate other features described herein.

### BRIEF DESCRIPTION OF THE DRAWINGS

The disclosure is described in further detail below by way of example and with reference to the accompanying drawings, in which:

FIG. 1A is a schematic of a circuit showing an example leakage current path,

FIG. 1B is a schematic of a further circuit showing an example leakage current path,

FIG. 1C is a schematic of a further circuit showing an example leakage current path,

FIG. 1D is a schematic of a further circuit showing an example leakage current path;

FIG. 2 is a flow chart of a computer implemented method of automatically searching for one or more leakage current paths in an electronic circuit in accordance with a first embodiment of the present disclosure;

FIG. 3A is a schematic of an example embodiment of an electronic circuit that may be subject to current leakage,

FIG. 3B is the corresponding graph of FIG. 3A;

FIG. 4 is a schematic of an example circuit design description for an electronic circuit, being a graph corresponding to the circuit; and

FIG. 5A is a schematic of a computer system configured to function as an automatic leakage current detection system in accordance with a second embodiment of the present disclosure,

FIG. 5B is a schematic of a specific implementation of the computer system of FIG. 5A in accordance with a third embodiment of the present disclosure.

### DETAILED DESCRIPTION

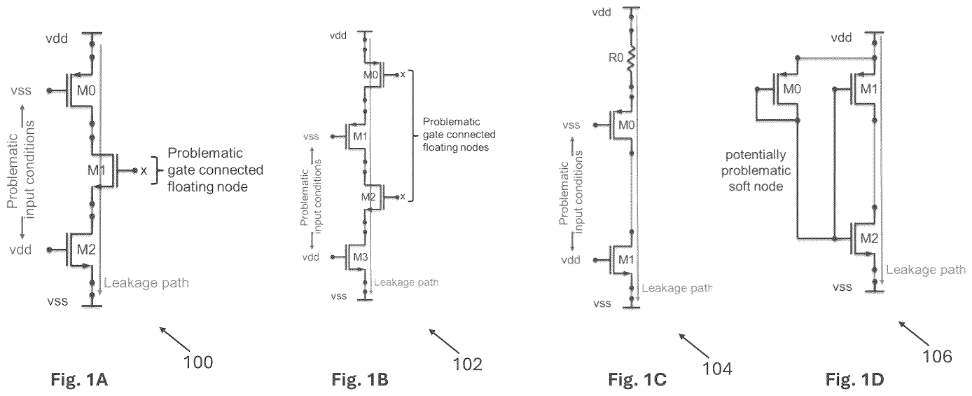

FIG. 1A is a schematic of a circuit 100 comprising field-effect transistors (FET) M0, M1, M2 coupled in series between supply voltage vdd, vss, and showing an example leakage current path through these FETs.

One potential cause of current leakage in an analog block may be undriven nodes (also known as “floating nodes”), in particular floating gates of FETs. A floating gate solely does not necessarily indicate a leakage path. For example, a leakage path may not be formed if the surrounding devices are not conducting. Additionally, sometimes current leakage occurs only when a circuit is subjected to certain input conditions. For example, inputs from the controller and/or floating nodes may act together to form a leakage path.

In the present example, a leakage path may form from vdd down to vss via the FETs M0, M1, M2. This leakage path is subject to specific input conditions. There are two inputs in the circuit 100. Specifically, there is a first input to the gate terminal of the FET M0 and a second input to a gate terminal of the FET M2. The inputs are received from a digital controller (not shown) and there are four possible combinations of values on these inputs, with one combination (as shown in the schematic) permitting a leakage path to form. The floating (i.e. undriven) gate of the FET M1 allows this leakage path to form as the residual charge on this node may reduce the impedance of M1.

FIG. 1B is a schematic of a circuit 102. In the present example, two floating nodes may contribute to a leakage current path, together with the specific set of input conditions shown in the example.

In the circuit 102, a leakage path may form from vdd down to vss via the transistors M0, M1, M2, M3. As before, the leakage path is subject to input conditions (the inputs driving the gates of M1 and M3).

Current leakage may be caused by an unintentional conducting path that is independent of floating nodes. For example, a resistor ladder or a current mirror may leak current if inadvertently left enabled during a period where the overall circuit is meant to be disabled.

FIG. 1C is a schematic of a circuit 104 comprising a resistor R0 and the FETs M1, M2. In the circuit 104, there are no floating nodes, but certain input conditions may result in a leakage path being formed from vdd down to vss via devices R0, M0, M1.

As another example, current leakage may be caused by “soft” nodes, which are nodes driven only by devices with high impedance such as diodes, resistors, or diode-connected FETs. A diode connected FET is a FET having its gate terminal connected to its drain terminal, such that the device acts like a diode—such diode-connected FETs may have high impedance.

FIG. 1D is a schematic of a circuit 106 illustrating a further source of a leakage current path. In the circuit 106 there are no floating nodes, but a leakage path may still form.

In the present example, the transistor M0 is a diode-connected FET. The diode-connected FET M0 may have a high impedance so that the node connected to the gates of M1 and M2, while not floating, is considered “soft”. Depending on the analog characteristics of the devices, the driving strength of the FET M0 may be insufficient and so the voltage on the “soft” node may be significantly below vdd, thereby allowing a leakage path to form.

As explained above, a specific set of input conditions may result in current leakage. In other words, leakage may be conditional on the state of inputs from a controller, such as a digital controller.

Some inputs, called fixed inputs, may be driven externally to a known voltage level (e.g. vdd or vss). Optionally, voltage levels in the circuit can be represented by ranked tokens, e.g. non-negative integers. For example, tokens 0, 1, 2, 3 might represent voltages close to −5v, 0v, 2.5v and 5.0v, respectively.

Other inputs may be undriven externally while the analog circuit may either drive them or leave them floating. Such inputs may be called floating inputs.

Furthermore, some inputs may be driven externally to an unknown value. For example the inputs from the digital controller are usually driven by the controller to either vdd or vss, but it is not known which of these values is used for each input, so for N such inputs, where N is an integer greater than or equal to one, a leakage current detection tool may check all 2^{N} combinations of values. Such inputs may be called toggle inputs.

As can be understood based on the leakage current examples provided by FIG. 1A-1D, the possible causes for current leakage are many, and consequently the exploration space is significant. Even if the only cause of potential leakage was input conditions, like in the example of FIG. 1C, the running time for analyzing all conditions emerging from the possible inputs is exponential in relation to the number of toggle inputs. In other words, it is computationally expensive to exhaustively check for leakage, and so it is infeasible to do it manually for realistic circuits.

The floating nodes checker method, as introduced previously, may be summarised as follows:

Using a graph representation of the circuit, for each combination of values of toggle inputs:
1. Skip some input combinations that are removed by heuristics or to reduce the search time (an optional step).
2. Simplify the circuit for the current combination of values (an optional step).
3. Keep propagating known voltage levels to nodes of the circuit, until no further propagation is possible; nodes with no propagated voltage level are considered floating.
4. Identify floating nodes connected to gates of FETs.
5. For each such floating node (or a combination of several neighboring ones):
   a. starting from the floating node FET try to find a path from this node to vss and
   b. starting from the floating node FET try to find a reverse path from this node to vdd via conducting devices.
6. If the above paths are found, report the combination of the two paths as a leakage path.

The existing floating nodes checker algorithm suffers from several disadvantages:
Exploring all combinations of values of toggle inputs is computationally expensive, and limiting the explored combinations may miss leakage paths.
Simplifying the circuit for each combination of toggle input values is computationally expensive; moreover, it causes problems when reporting the leakage path, as it is computed on the reduced circuit but needs to be expressed as a path in the original circuit for debugging.
Enumerating subsets of floating nodes and finding paths for each subset is sub-optimal, and limiting such subsets (e.g. to two nodes as often done in practice) may miss leakage paths (for example, issues may arise by three floating nodes acting together).
The algorithm only applies to cases where floating nodes are present and cannot identify leakage paths due to other reasons, such as was described in relation to FIG. 1C.

It will be appreciated that other known systems have similar disadvantages to the existing floating nodes checker algorithm, or other disadvantages as explained earlier.

Embodiments of the present disclosure mitigate or overcome one or more of the above issues.

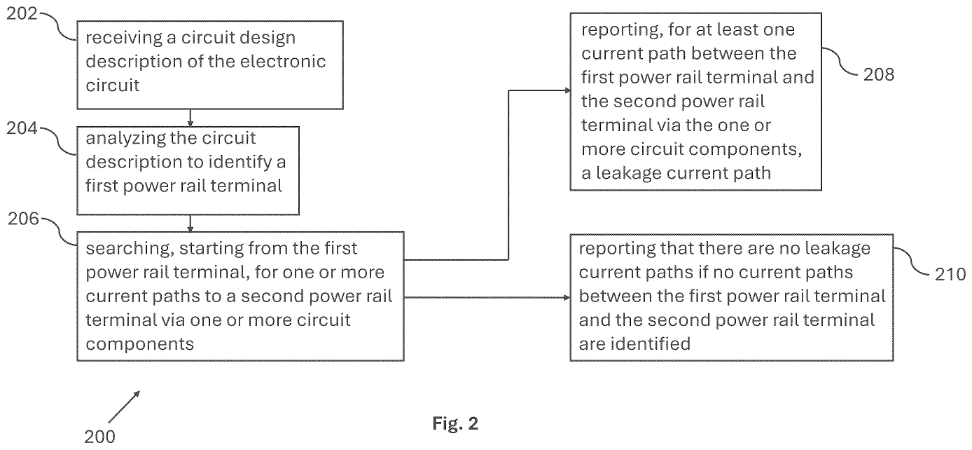

FIG. 2 is a flow chart of a computer implemented method 200 of automatically searching for one or more leakage current paths in an electronic circuit in accordance with a first embodiment of the present disclosure.

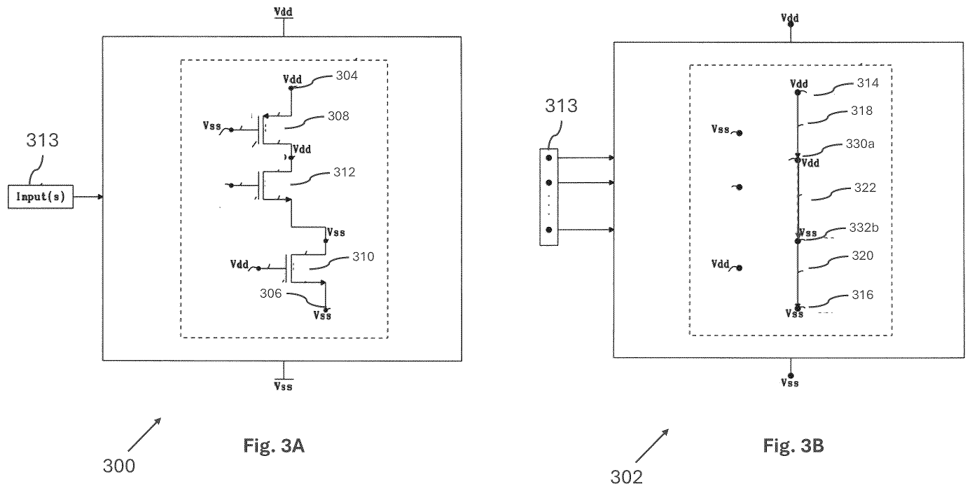

FIG. 3A is a schematic of an example embodiment of an electronic circuit 300 that may be subject to current leakage. FIG. 3B is a schematic of a circuit design description 302 of the electronic circuit 300, and is the corresponding graph of FIG. 3A.

It will be appreciated that FIG. 3A and FIG. 3B are provided as examples to aid in the interpretation of the method 200 of FIG. 2, and that the method 200 may be applicable to any electronic circuit represented by a circuit design description, in accordance with the understanding of the skilled person.

In the present example, the electronic circuit 300 comprises power rail terminals 304, 306 and circuit components 308, 310, 312, where the circuit components comprise transistors, and are specifically, field effect transistors (FETs). The power rail terminal 304 is configured to receive a supply voltage Vdd and the power rail terminal 306 is configured to receive a supply voltage Vss.

The electronic circuit 300 may be subject to input conditions 313. In the present example, the current input condition as shown is the application the supply voltage Vss to a gate terminal of the transistor 308 and the supply voltage Vdd to a gate terminal of the transistor 310. In the present example, a gate terminal of the transistor 312 has a floating node. It will be clear that the electronic circuit 300 is the same as the circuit 100 of FIG. 1A and therefore has a leakage path.

The method 200 comprises receiving the circuit design description 302 of the electronic circuit 300 at a step 202.

The method 200 further comprises analysing the circuit description 302 to identify the power rail terminal 304, at a step 204.

The method 200 further comprises searching for one or more current paths from the power rail terminal 304 to the power rail terminal 306 via one or more of the circuit components 308, 310, 312, at a step 206. The step 206 performed by the method 200 begins at the power rail terminal 304.

Each of the one or more circuit components 308, 310, 312 may comprise one or more conducting devices and/or one or more FETs, each with a floating gate.

In the present example, the circuit components 308, 310 are transistors that are conducting devices, and the circuit component 312 is a transistor that is a floating gate FET.

The method 200 further comprises reporting a leakage path, for at least one current path identified between the power rail terminal 304 and the power rail terminal 306 via the one or more circuit components 308, 310, 312, at a step 208.

In a specific embodiment, the method 200 may comprise reporting a leakage path, for each current path identified between the power rail terminal 304 and the power rail terminal 306, up to a set limit of reported leakage paths. The set limit may, for example, be three leakage paths.

Alternatively, or additionally, the method 200 comprises reporting that there are no leakage current paths if no current paths are identified between the power rail terminal 304 and the power rail terminal 306, at a step 210

In a further embodiment, the method 200 may further comprise defining a plurality of input conditions 313 for the electronic circuit 300. Each input condition 313 of the plurality of input conditions may result in the electronic circuit 300 being in a different state of operation. Searching for the one or more current paths may comprise applying each of the input conditions 313 to the circuit design description, and then searching for current paths for each of the input conditions 313. Additionally or alternatively, method 200 allows searching for current paths for each state of electronic circuit 300 corresponding to one of the plurality of input conditions 313. As such, method 200 enables identifying leakage paths for circuits that may have more than 10, 50, 100 or even 1000 possible states of operation. As discussed previously, leakage current paths may only occur for specific input conditions, and therefore it may be necessary to consider different input conditions that may occur during operation of the electronic circuit 300 to comprehensively identify leakage current paths. The input conditions 313 may comprise voltage levels. For example, FIG. 3A shows a single input condition provided by the supply voltages Vss, Vdd provided to the gate terminals of transistors 308, 310.

Defining the plurality of input conditions 313 may comprise identifying possible input settings for the electronic circuit 300 that it may encounter during operation, removing one or more of the input settings based on a pre-defined condition, and then generating the plurality of input conditions 313 based on the plurality of input settings after removal.

For example, the plurality of input settings may be an exhaustive list of possible inputs that the electronic circuit 300 will encounter during operation or given by a Boolean formula that would evaluate to TRUE for possible inputs. To reduce the search time of the method 300, it can be beneficial to omit unnecessary input conditions, and this may be achieved by defining certain conditions for the removal of unnecessary input settings. The pre-defined conditions may, for example, be determined using heuristics.

The input conditions 313 may be voltage levels on input wires, so propagation takes them into account for fixed inputs. For toggle inputs, the combinations may be enumerated and each one may be processed separately.

The method 200 may further comprise identifying the one or more floating gate FETs prior to searching for the one or more current paths. Identifying one or more floating gate FETs may comprise propagating voltage levels through nodes of the circuit design description 302, identifying nodes having no propagated voltage as being floating node, and identifying FETs in the circuit design description having gates which are floating nodes as being floating gate FETs.

The circuit design description 302 may be a graph data structure comprising nodes and one or more arcs. Graph data structures and their use in representing electronic circuits is well known in the technical field. Each node is coupled to another node by at least a single arc, and each node represents a terminal of one of the circuit components of the electronic circuit 300. Each node (wire) connects one or more terminals of one or more components, e.g. in FIG. 1D the soft node connects four terminals in total. Each arc represents at least a portion of a path through one of the circuit components of the electronic circuit 300. The circuit design description 302 as shown in FIG. 3B is a directed graph representation of the electronic circuit 302.

For example a path may be a sequence of one or more arcs. For example, an arc may represent a potential electric conduction between pins of a component.

It will be appreciated that in further embodiments, the circuit design description 302 may be provided in a different format and is not limited to graph data structures. For example, the circuit design description 302 may be any suitable description of the circuit that comprises circuit component information and connectivity information for performing the methods of the present disclosure to identify leakage current paths, in accordance with the understanding of the skilled person.

In the present example, the circuit design description 302 comprises a power rail node 314 that represents the power rail terminal 304 and a power rail node 316 that represents the power rail terminal 306. The circuit design description 302 further comprises an arc 318 that represents a conductive path through the circuit component 308, an arc 320 that represents a conductive path through the circuit component 310, and an arc 322 that represents a conductive path through the circuit component 312. The electronic circuit 300 further comprises terminals 324a, 326a, 328a, 330a, 332a. The circuit design description 302 further comprises nodes 324b, 326b. 328b, 330b, 332b. The nodes 324b, 326b. 328b, 330b, 332b represent the terminals 324a, 326a, 328a, 330a, 332a, respectively.

In a specific embodiment, searching for the one or more current paths may comprise traversing from the power rail node 314 to the power rail node 316 via at least one of the arcs 318, 320, 322, for example, via one or more successive nodes 330a, 332b.

It will be appreciated that as the circuit components 308, 310, 312 may conduct in either direction, the arcs 318, 320, 322 shown in FIG. 3B are not entirely accurate and each should be illustrated as a pair of arcs going in opposite directions. It will be appreciated that FIG. 3B is shown for illustrative purposes.

A specific embodiment of the method 200 may be summarised as follows:

For a given circuit:
1. Detect floating nodes by propagating known voltage levels to the nodes of the circuit, until no further propagation is possible; nodes with no propagated voltage level are considered floating.
2. Starting from the power rail terminal 304 at the supply voltage Vdd, identify as a leakage path any path from the power rail terminal 304 to the power rail terminal 306 at the supply voltage Vss via conducting devices 308, 310 and FETs with floating gates 312.

A specific embodiment of the method 200 may be summarised as follows:

Using a graph representation of the electronic circuit 300, for each combination of values of toggle inputs (provided by the input conditions 313):
a. Skip some input combinations that are removed by heuristics or to reduce the search time (this step is optional).
b. Keep propagating known voltage levels to nodes of the circuit, until no further propagation is possible; nodes with no propagated voltage level are considered floating.
c. Find a path from the power rail terminal 304 at the supply voltage Vdd to the power rail terminal 306 at the supply voltage Vss via conducting devices 308, 310 and FETs with floating gates 312.
d. If the above path is found, report it as a leakage path.
e. Multiple such paths may exist, in which case the algorithm may optionally continue the search and report several leakage paths (e.g. all or up to a certain limit); optionally, it may try to provide a good coverage by not reporting paths similar to previously reported ones (e.g. caused by the same set (or a subset) of floating nodes, and/or having many devices in common).

Two differences between embodiments of the present disclosure and the known floating nodes checker method are as follows:
1. A first difference is that embodiments of the method 200 look for a single path from the supply voltage Vdd to the supply voltage Vss irrespective of the number of floating nodes and combinations thereof, whereas the known floating nodes checker method prior art algorithm looks for a pair of paths for each floating node and each combination thereof. For example, if there are N floating nodes and all their combinations of size up to 3 are explored to trade off coverage for performance, the known method performs 2*(N+ N(N−1)+N(N−1)(N−2)) searches for paths, while embodiments of the present disclosure may perform a single search irrespective of the number of floating nodes and provides complete coverage, without the need to trade it off for performance.
2. A second difference is that there is no need to simplify the circuit for each combination of input values for embodiments of the present disclosure.

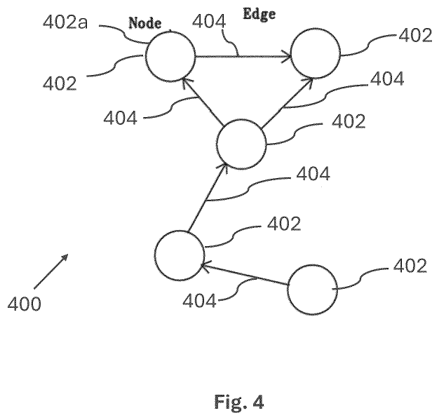

FIG. 4 is a schematic of an example circuit design description 400 for an electronic circuit (not shown). A specific embodiment of the method 200 may be applied to the circuit design description 400 to identify leakage current paths of the associated electronic circuit.

The circuit design description 400 is a graph data structure comprising a plurality of nodes 402 which are coupled together via arcs 404 (which may also be called “edges”). It will be appreciated that the example shown in FIG. 4 is a well-known type of circuit representation as is commonly used in circuit simulations.

As discussed previously, each node 402 represents a terminal of a circuit component and each arc 404 represents at least a portion of a path through a circuit component.

Each node (wire) connects one or more terminals of one or more components, e.g. in FIG. 1D the soft node connects four terminals in total.

As discussed previously, arcs may represent conductive components or FETs having floating gates.

It will be appreciated that it is possible for a circuit component to contribute more than one arc. For example, a double switch with two input terminals and two output terminals, or a FET with one gate controlling two channels, may contribute more than one arc to the graph. A normal FET may contribute two arcs going in opposite directions.

The data structure provided by the circuit design description 400 is created so that it can be traversed across all connected nodes. A traversal is a journey that starts as a certain node, follows the direction of arcs outgoing from that node, reaches another node (and so on) and finally reaches a destination node. Interrogating the data structure is achieved by a data processing system provided with instructions which can trace a path through successive nodes in the structure. The traversal process is undertaken as part of step 206 of the method 200 in searching for one or more current paths.

An example crawling method for the application of the step 206 for a computer system performing the method 200 may be described as follows:
1. The process begins at a node 402a of the data structure that represents a first power rail terminal (for example being at the supply voltage Vdd).
2. All edges connected to the node 402a are considered by the system. Each edge represents a conducting device (under the specific input condition, as may be referred to as a stimulus set-up condition).
3. The edges at the node 402a may be incoming (i.e. depositing charge at this node) or outgoing (i.e. transporting charge out of this node).
4. The system picks an outgoing edge (if it crawls along the direction of current, such as to find a Vss destination) and reaches the other side of the edge (which is another node). Alternatively, it may also pick an incoming edge (if it crawls against the direction of current, such as to find a Vdd destination).
5. The system repeats the steps 1-4 for the newly arrived node and continues through the data structure following the same rule until it reaches a second power rail terminal (for example being at the supply voltage Vss).
6. The crawling is deemed to be successful if it reaches its intended destination (Vdd or Vss). Otherwise it is deemed to be unsuccessful.

Traversing graphs to find paths is a well studied problem with lots of efficient algorithms (for example https://en.wikipedia.org/wiki/Depth-first_search)

The above steps may be repeated for all possible paths from the node 402a to a node being representative of the second power rail terminal. The system may then report each leakage path identified, at the step 208, or report that no leakage current paths have been identified, at the step 210.

The method 200 is well suited to being implemented using a Boolean Satisfiability (SAT) Solver. In a practical implementation of the method 200 using a Boolean SAT Solver, there has been found to be an improved runtime performance when compared to known systems and the following advantages:
Very significant speedups, especially for larger designs.
An over 2,500,000 times faster performance in identifying current leakage.
Successfully completes on all benchmarks.
Usually takes no more than a second, and less than 53 seconds on the hardest benchmark in our collection. The known system was terminated after 4.5 days after which it was still running.
Exhaustive coverage of input conditions.
Improved performance whenever an improved version of the (SAT) solver is released by its developer.

The example illustrated in FIG. 4 uses a path finding algorithm applied to a graphical data structure. It will be appreciated that further embodiments may use other data structures for path finding, and therefore the present disclosure is not intended to be limited to the use of graphs for path finding, in accordance with the understanding of the skilled person.

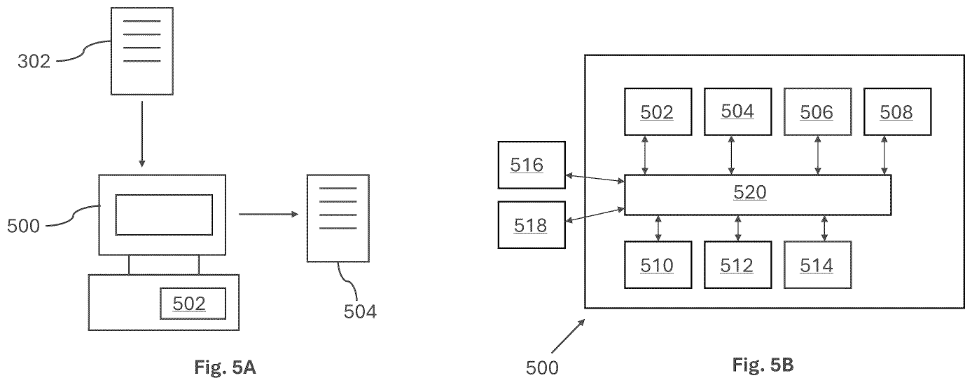

FIG. 5A is a schematic of a computer system 500 configured to function as an automatic leakage current detection system configured to perform the steps of the method 200 in accordance with a second embodiment of the present disclosure.

In the present example, the computer system 500 comprises a non-transitory computer readable storage medium 502 comprising instructions that when executed by the computer system 500 cause the computer system 500 to carry out the steps of the method 200 and thereby function as the automatic leakage current detection system.

It will be appreciated that although illustrated within the computer system 500, the non-transitory computer readable storage medium 502 may be an external component.

The computer system 500 may perform the steps of any of the embodiments of the method 200 described herein in accordance with the understanding of the skilled person.

During operation, the computer system 500 functioning as the automatic leakage current detection system receives the circuit design description 302 and outputs a report 504. The report 504 provides information on the leakage current paths, or the absence of leakage current paths in the electronic circuit 300. The report 504 may, for example, be a data file or it may refer to information displayed on a monitor for a user to review.

FIG. 5B is a schematic of a specific implementation of the computer system 500 in accordance with a third embodiment of the present disclosure. The computer system 500 may comprise a processor 504, a storage device 506, RAM 508, ROM 510, a data interface 512, a communications interface 514, a display 516 and an input device 518. The computer system 500 may comprise a bus 520 to enable communication between the different components.

The computer system 500 may be configured to load an application. The instructions provided by the application may be carried out by the processor 504. The application may be for automatic leakage current detection, with the instructions for the application being stored in the storage medium 502.

A user may interact with the computer system 500 using the display 516 and the input device 518 to instruct the computer system 500 to implement the methods of the present disclosure in automatically detecting leakage current paths in an electronic circuit design.

Embodiments of the present disclosure may be used to diagnose current leakage in electronic circuits such as analog circuits.

Embodiments of the present disclosure may provide reporting of conducting paths between supply voltage Vdd, Vss that are indicative of leakage current paths.

Embodiments of the present disclosure may be used to identify current leakage in electronic circuit designs having soft nodes, sequential elements, diode connected FETs and/or may be suitable for analysis of electronic circuits having multiple voltage levels.

Various improvements and modifications can be made to the above without departing from the scope of the disclosure.

1. A computer implemented method of automatically searching for one or more leakage current paths in an electronic circuit comprising:
receiving a circuit design description of the electronic circuit;
analyzing the circuit description to identify a first power rail terminal;
searching, starting from the first power rail terminal, for one or more current paths to a second power rail terminal via one or more circuit components;
reporting, for at least one current path between the first power rail terminal and the second power rail terminal via the one or more circuit components, a leakage current path; and/or reporting that there are no leakage current paths if no current paths between the first power rail terminal and the second power rail terminal are identified.

2. The computer implemented method of claim 1, wherein the circuit design description comprises circuit component information and connectivity information.

3. The computer implemented method of claim 2, wherein:
the circuit design description comprises a graph data structure comprising nodes and one or more arcs;
each of the one or more arcs connects a pair of distinct nodes;
each node connects one or more terminals of one of the one or more circuit components;
and each arc represents at least a portion of a path through one of the one or more circuit components.

4. The computer implemented method of claim 3, wherein searching for each of the one or more current paths comprises:
traversing from a first power rail node that represents the first power rail terminal to a second power rail node that represents the second power rail terminal via at least one of the one or more arcs.

5. The computer implemented method of claim 4, wherein traversing from the first power rail node to the second power rail node comprises traversing from the first power rail node to the second power rail node via one or more successive nodes.

6. The computer implemented method of claim 1, comprising:
defining a plurality of input conditions for the electronic circuit; wherein:
searching for the one or more current paths comprises:
applying each of the plurality of input conditions to the circuit design description;
and searching for the one or more current paths for each of the plurality of input conditions.

7. The computer implemented method of claim 6, wherein the plurality of input conditions comprises voltage levels.

8. The computer implemented method of claim 6, wherein:
defining the plurality of input conditions for the electronic circuit comprises:
identifying a plurality of input settings for the electronic circuit;
removing one or more of the plurality of input settings based on a pre-defined condition; and
generating the plurality of input conditions, using the plurality of input settings after removal.

9. The computer implemented method of claim 1, wherein the one or more circuit components comprises:
one or more conducting devices; and/or one or more floating gate field effect transistors (FET), each with a floating gate.

10. The computer implemented method of claim 9, further comprising identifying the one or more floating gate FETs prior to searching for the one or more current paths.

11. The computer implemented method of claim 10, wherein identifying the one or more floating gate FETs comprises:
propagating voltage levels through nodes of the circuit design description;
identifying nodes having no propagated voltage level as being floating nodes; and
identifying FETs in the circuit design description having gates with floating nodes as being floating gate FETs.

12. The computer implemented method of claim 9, comprising:
defining a plurality of input conditions for the electronic circuit; wherein:
searching for the one or more current paths comprises:
applying each of the plurality of input conditions to the circuit design description by applying each of the plurality of input conditions to at least one of the one or more circuit nodes; and
searching for the one or more current paths for each of the plurality of input conditions.

13. The computer implemented method of claim 12, wherein defining the plurality of input conditions for the electronic circuit comprises identifying a plurality of input settings for the electronic circuit by performing a search using a solver.

14. The computer implemented method of claim 13, wherein the solver is a SAT solver.

15. The computer implemented method of claim 12, wherein:
defining the plurality of input conditions for the electronic circuit comprises:
identifying a plurality of input settings for the electronic circuit;
removing one or more of the plurality of input settings based on a pre-defined condition; and
generating the plurality of input conditions, using the plurality of input settings after removal.

16. The computer implemented method of claim 12, wherein:
at least one of the one or more conducting devices comprises a FET; and
applying each of the plurality of input conditions to at least one of the one or more conducting devices comprises applying each of the plurality of input conditions to at least one of the one or more circuit nodes.

17. The computer implemented method of claim 1, wherein searching for the one or more current paths comprises using a solver to search for the one or more current paths.

18. The computer implemented method of claim 17, wherein the solver is a Boolean Satisfiability (SAT) solver.

19. An automatic leakage current detection system configured to:
receive a circuit design description of an electronic circuit;
analyze the circuit description to identify a first power rail terminal;
search, starting from the first power rail terminal, for one or more current paths to a second power rail terminal via one or more circuit components;
report, for at least one current path between the first power rail terminal and the second power rail terminal via the one or more circuit components, a leakage current path; and/or report that there are no leakage current paths if no current paths between the first power rail terminal and the second power rail terminal are identified.

20. A non-transitory computer-readable storage medium having stored thereon instructions that when executed by a computer cause the computer to carry out a method of automatically searching for one or more leakage current paths in an electronic circuit comprising:
receiving a circuit design description of the electronic circuit;
analyzing the circuit description to identify a first power rail terminal;
searching, starting from the first power rail terminal, for one or more current paths to a second power rail terminal via one or more circuit components;
reporting, for at least one current path between the first power rail terminal and the second power rail terminal via the one or more circuit components, a leakage current path; and/or reporting that there are no leakage current paths if no current paths between the first power rail terminal and the second power rail terminal are identified.
